(19) United States
(12) Patent Application Publication
(10) Pub. No.: US 2006/0054353 A1
(43) Pub. Date: Mar. 16, 2006

(54) Method and device for protection of a component or module

(75) Inventors: Richard Wallace, Jarfalla (SE); James D. MacDonald, Rockwall, TX (US)

Correspondence Address: BAKER BOTTS L.L.P.;PATENT DEPARTMENT, 98 SAN JACINTO BLVD., SUITE 1500, AUSTIN, TX, 78701-4039, US

(73) Assignee: Infineon Technologies AG

(21) Appl. No.: 11/225,578

(22) Filed: Sep. 13, 2005

Related U.S. Application Data
(63) Continuation of application No. PCT/SE04/00275, filed on Mar. 1, 2004.

(30) Foreign Application Priority Data
Mar. 13, 2003 (SE) SE 0300686-3

(51) Int. Cl. H05K 1/11; H05K 1/16; H05K 3/30

(52) U.S. Cl. 174/261; 174/260; 29/842; 29/832

(57) ABSTRACT

A connectivity from a module to a board is ordinary achieved with pads as via Land Grid Array (LGA), where an inner area of the module is provided with pads designated for electrical connectivity to corresponding points of connection on the board. To protect the component or the module and to increase the mechanical life time of the component or the module, the outer area of the component or the module (1) is provided with a peripheral outer line of pads forming a sacrifice pad area or pad ring (3), where individual pad or pads can be sacrificed without destroying the inner pads (2), which are designated for the electrical connectivity to corresponding points of connection on the board provided inside the sacrifice pad area or pad ring on the component or the module.

### CROSS-REFERENCE TO RELATED APPLICATIONS

This application is a continuation of co-pending International Application No. PCT/SE2004/000275 filed Mar. 1, 2004, which designates the United States of America, and claims priority to Swedish application number 0300686-3 filed Mar. 13, 2003, the contents of which are hereby incorporated by reference in their entirety.

### TECHNICAL FIELD

The present invention relates to a method and a device for protection of a component or a module, which method and device even would be able to increase the mechanical lifetime of the component or the module. A connectivity from a module to a board is ordinary achieved with pads as via a Land Grid Array (LGA), where an inner area of the module is provided with pads designated for electrical connectivity to corresponding points of connection on the board.

### BACKGROUND

The connectivity from a module to a board is ordinary achieved with pads on the module, which pads when the module is assembled onto the board are provided to be contacted with leads or contact points on the board. The connected pads are difficult to inspect and it is even difficult to determine: or estimate the mechanical lifetime of the module with reference to the pads.

### SUMMARY

To protect a component or a module and to increase the mechanical life time of the component or the module, the outer area of the component or the module is provided with a peripheral outer line of pads forming a sacrifice pad area or pad ring, where individual pad or pads can be sacrificed without destroying the pads, which are provided inside the sacrifice pad area or pad ring on the component or the module. The mechanical lifetime of a module is usually measured by performing rapid temperature change tests of the module, while eventually changes in the configuration of the module and its pads are detected and registered. When using a sacrifice pad area or pad ring on a component or a module and performing rapid temperature change tests, it will be easier to detect damage on the component or the module, because pad or pads of the sacrifice pad area or pad ring will first be destroyed and any deformation or rupture of any pad of the pad area or pad ring can easily be detected and registered as a measure of the quality of the component or the module.

### BRIEF DESCRIPTION OF THE DRAWINGS

FIG. 1 is a bottom view of a rectangular component or module with many connections, where the inner pads are uncoloured/white and the outer pads are coloured/grey and constituted to be a sacrifice pad area or pad ring according to the invention.

FIG. 2 is a bottom view of a circular component or module with many connections, where the inner pads are uncoloured/white and the outer pads are coloured/grey and constituted to be a sacrifice pad area or pad ring according to the invention.

FIG. 3 is a bottom view of a rectangular component or module with few connections, where the inner few pads are uncoloured/white and the outer pads are coloured/grey and constituted to be a sacrifice pad area according to the invention.

FIG. 4 is a bottom view of a rectangular component or a module with many connections, where the inner pads are uncoloured/white and the outer pads are coloured/grey and constituted to be a sacrifice pad area or pad ring according to the invention and where at least one pad is removed from the pad area or pad ring to form an asymmetric sacrifice pad area or pad ring.

### DETAILED DESCRIPTION

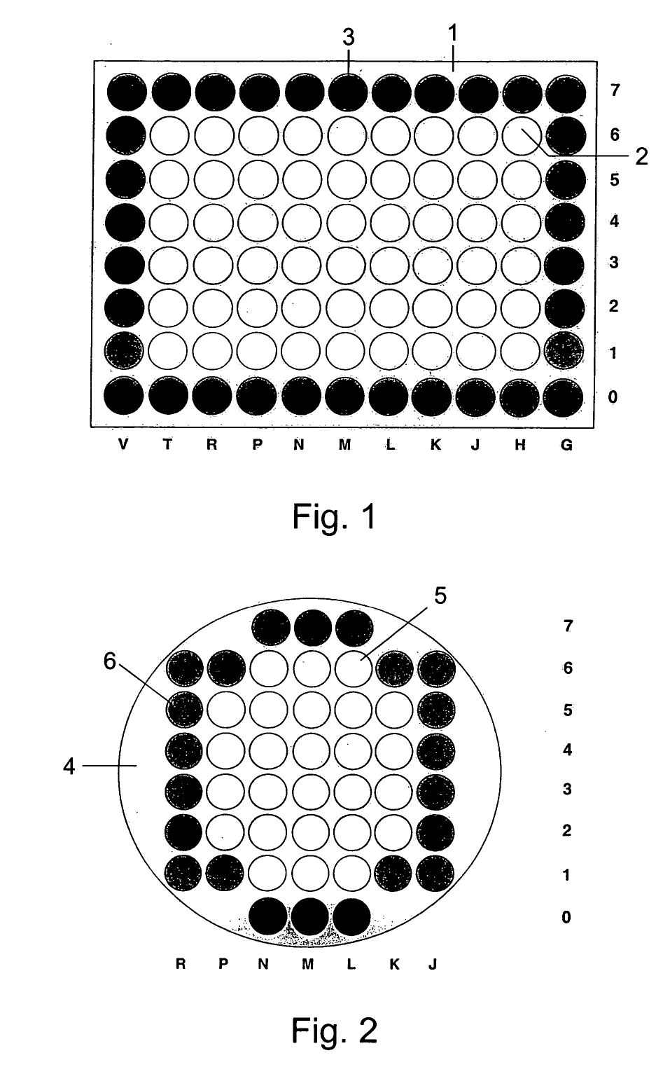

In FIG. 1 a preferred, rectangular component or module 1 is shown, where 6×9 inner pads 2 are surrounded by an outer pad area or pad ring 3 consisting of four outer lines of pads: 2×10+2×7 pads. The inner pads 2 are provided to be ordinary pads, which function to be connected to a board with corresponding contact points on the board, wherein each pad on the component or the module enables contact with a corresponding contact point on the board for transforming electrical signals between the component or the module and the board. The outer pad area or pad ring 3 constitutes the sacrifice pad area or pad ring and has normally no electrical contact function, but any pad in this pad area or pad ring can in addition be used as test point/points in a production line and can be connected to a detection device, wherein individual pads of the sacrifice pad area or pad ring can be used as internal test points and in most cases their existence has no use for a final user. Pads in the sacrifice pad area or pad ring can be broken as open circuits and this will in most cases not effect the operation of the component or the module.

In FIG. 2 a circular component or module 4 is shown, where 26 inner pads 5 are surrounded by an outer pad area or pad ring 6. The inner pads 5 are provided to be ordinary pads, which function to be connected to a board with corresponding contact points on the board, wherein each pad 5 on the component or the module enables contact with a corresponding contact point on the board for transforming electrical signals between the component or the module and the board. The outer pad area or pad ring 6 constitutes the sacrifice pad area or pad ring and has normally no electric contact function, but any pad in this pad area or pad ring can in addition be used as test point/points in a production line, wherein individual pads of the sacrifice pad area or pad ring can be used as internal test points and in most cases their existence has no use for a final user. Pads in the sacrifice pad area or pad ring can be broken as open circuits and this will in most cases not effect the operation of the component or the module.

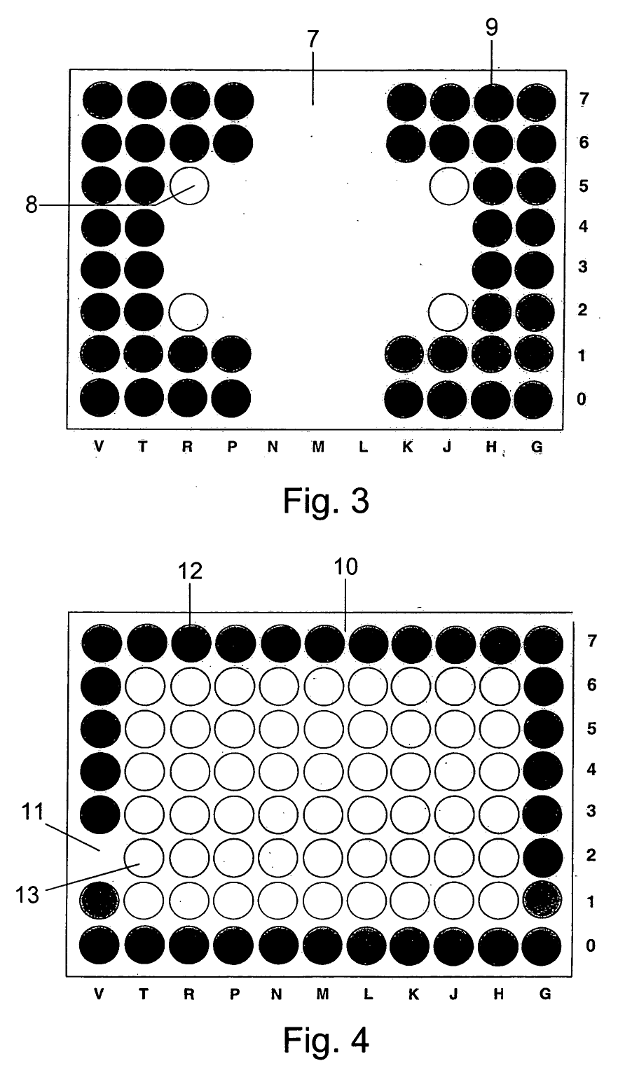

In FIG. 3 a rectangular component or module 7 is shown, where only 4 inner pads 8 are surrounded by an outer pad area consisting of 48 pads 9. The inner pads 8 are provided to be ordinary pads, which function to be connected to a board with corresponding contact points on the board, wherein each pad on the component or the module enables contact with a corresponding contact point on the board for transforming electrical signals between the component or the module and the board. The outer pad area 9 constitutes the sacrifice pad area and has normally no electrical contact function, but any pad in the pad area can in addition be used as test point/points in a production line, wherein individual pads of the sacrifice pad area can be used as internal test points and in most cases their existence has no use for a final user. Pads in the sacrifice pad area can be broken as open circuits and this will in most cases not effect the operation of the component or the module.

The mechanical lifetime of a component or module will be increased due to the existence of a sacrifice pad area or pad ring. The sacrifice pad area or pad ring gives for the first the inner connections points a functioning mechanical protection against horizontal and/or vertical loads. When performed rapid temperature change tests parts of the outer pad area or pad ring will for the second be the first destroyed part of the component or the module before any part of the inner part inside the pad area or pad ring will be destroyed. With the outer pad area or pad ring it will be easy to determine the mechanical life time of the component or the module, only by detection and registration under fatigue test or performed rapid temperature change test when the first pad of the sacrifice pad area or pad ring will be destroyed a very well defined life time of the component or the module can be determined. At the tests the pad in any corner of the pad area or pad ring on the component or the module will be firstly destroyed and then the adjacent placed pads will be destroyed and so on, because the mechanical stress has a maximum in the corners of the component or the module.

With a sacrifice pad area or pad ring, where every formed pad in the pad area or pad ring is grounded, a grounded screening cage can be achieved, which electrically protects the electronic circuits and elements of the component or the module placed inside of the pad area or pad ring. It is even more economical and easy to produce a sacrifice pad area or pad ring consisting of many individually placed pads in line compared with a metal bar on the board, when producing hundreds of ordinary pads on a component or module, of which the outer pads function to be the sacrifice pad area or pad ring of the component or the module. The mechanical protection is easy to produce together with the other pads. With the outer pads in the sacrifice pad area or pad ring of the component or the module connected to the board it is even possible to visually inspect the connected pads inside the pad area or pad ring to determine the quality of the connections compared with if there is a homogenous pad ring or bar outside the inner connected pads. If the quality of the pads of the pad area or pad ring can be determined the quality of the inner pads can be estimated based on the observations of the pads of the pad area or pad ring. Without the pad area or pad ring it is difficult to determine or estimate the quality of the connections of the inner pads.

For high frequency module application a measuring of the return loss of the antenna port can monitor the condition of the sacrifice pad area or pad ring. The sacrifice pad area or pad ring can be connected to ground and when the sacrifice pad area or pad ring grounds start to diminish, then this can be monitored by an increased return loss on the antenna port and there will be a risk for damage of the component or the module.

In order to place a component or module 10 correct on a board a single pad 11 can be removed from the sacrifice pad area or pad ring 12, see FIG. 4, without essentially influencing the effect of the grounded screening cage. Due to the asymmetry the user of the component or the module can not place the device 180 degrees incorrect. With the asymmetry and the removed pad from the sacrifice pad area or pad ring sensitive module signals such as RF and balanced data lines are not required to be routed through several layers. The sensitive signals can be routed on a top layer of the board directly to a connection point or pad 13 on the mounted module.

When a component or module is assembled onto a board, the purpose of the sacrifice pad area or pad ring is to increase the mechanical lifetime of the component or the module. The mechanical lifetime is usually measured by performing rapid temperature change tests. After certain number of temperature cycles in a lifetime test environment the outer region of the pad area or the pad ring will start to break first. This will not effect the performance of the component or the module since all the electrical interconnects are in the centre of the LGA. The using of the sacrifice pad area or pad ring concept will increase the mechanical lifetime of the component or the module and may provide an additional number of test points in combination with detection devices for example in a production line.

It will be obvious that the invention may be varied in many ways. Such variations are not to be regarded as a departure from the scope of the invention. All such modifications as would be obvious to one skilled in the art are intended to be included within the scope of the appended claims.

What is claimed is:

1. A method for protection of a component or module comprising pads for connecting the component or the module with a board with corresponding contact points, the method comprising the step of providing the component or the module with an outer sacrifice pad area or pad ring, that consists of pads placed outside of inner pads, which are provided to be connected with contact points of the board, wherein the inner pads will be protected by the sacrifice pad area or pad ring and a pad or pads of the sacrifice pad area or pad ring will be destroyed before the inner pads will be destroyed under the mechanical lifetime of the component or module.

2. A method according to claim 1, comprising the steps of:
removing at least one pad of the sacrifice pad area or pad ring to make the ring asymmetric,
correctly placing the component or the module on the board, and
routing sensitive signals on a top layer of the board to another pad of the component or the module.

3. A method according to claim 1, comprising the step of providing at least one pad of the sacrifice pad area or pad ring to be connected to a detection device.

4. A method according to claim 1, comprising the step of providing pads in the sacrifice pad area or pad ring to form part of a grounded screening cage.

5. A device for protection of a component or module comprising:
pads for connecting the component or the module with a board with corresponding contact points, and
an outer sacrifice pad area or pad ring on the component or the module outside of inner pads which are provided to be protected by the sacrifice pad area or pad ring and a pad or pads of the sacrifice pad area or pad ring will be destroyed before the inner pads will be destroyed under the mechanical life time of the component or module.

6. A device according to claim 5, wherein at least one pad of the sacrifice pad area or pad ring has been removed from the pad ring to make the ring asymmetric, and a user of the component or the module can correctly place the component or the module on the board and sensitive signals can be routed on a top layer of the board to another pad of the component or the module.

7. A device according to claim 5, wherein at least one pad of the sacrifice pad area or pad ring is provided to be connected to a detection device.

8. A device according to claim 5, wherein pads in the sacrifice pad area or pad ring are provided to form part of a grounded screening cage.

9. A component or module comprising:
a first surface area comprising inner pads for connecting the component or module with another device with corresponding contact points, and
a second surface area defining a sacrifice pad area or pad ring on the component or the module outside the first surface, wherein the inner pads are provided to be protected by the sacrifice pad area or pad ring and a pad or pads of the sacrifice pad area or pad ring will be destroyed before the inner pads will be destroyed under the mechanical life time of the component or module.

10. A component or module according to claim 9, wherein at least one pad of the sacrifice pad area or pad ring has been removed from the pad ring to make the ring asymmetric, and a user of the component or the module can correctly place the component or the module on the board and sensitive signals can be routed on a top layer of the board to another pad of the component or the module.

11. A component or module according to claim 9, wherein at least one pad of the sacrifice pad area or pad ring is provided to be connected to a detection device.

12. A component or module according to claim 9, wherein pads in the sacrifice pad area or pad ring are provided to form part of a grounded screening cage.
